(19) United States
(12) Patent Application Publication
(10) Pub. No.: US 2026/0231420 A1
(43) Pub. Date: Aug. 6, 2026

(54) SEMICONDUCTOR MEMORY DEVICE AND METHOD OF MANUFACTURING SEMICONDUCTOR MEMORY DEVICE

(71) Applicant: Kioxia Corporation, Tokyo (JP)

(72) Inventor: Hiroyasu SATO, Yokkaichi (JP)

(73) Assignee: Kioxia Corporation, Tokyo (JP)

(21) Appl. No.: 19/324,976

(22) Filed: Sep. 10, 2025

(30) Foreign Application Priority Data
Feb. 3, 2025 (JP) 2025-015834

(51) Int. Cl. H10B 43/35; H10B 43/27

(52) U.S. Cl. CPC H10B 43/35; H10B 43/27

(57) ABSTRACT

In a semiconductor memory device, a charge storage film includes a plurality of first convex parts and a plurality of second convex parts. The plurality of first convex parts are disposed between a plurality of first conductive layers and a semiconductor film in a first region, and are continuous with each other in a stacking direction. Each of the plurality of first convex parts protrudes toward the first conductive layer at a position corresponding to the first conductive layer. The plurality of second convex parts are disposed between a plurality of second conductive layers and the semiconductor film in a second region, and are separated from each other in the stacking direction. Each of the plurality of second convex parts protrudes toward the second conductive layer at a position corresponding to the second conductive layer.

### CROSS-REFERENCE TO RELATED APPLICATION

This application is based upon and claims the benefit of priority from Japanese Patent Application No. 2025-015834, filed Feb. 3, 2025, the entire contents of which are incorporated herein by reference.

### FIELD

Embodiments described herein relate generally to a semiconductor memory device and a method of manufacturing the semiconductor memory device.

### BACKGROUND

A semiconductor memory device having a three-dimensional structure is known in which a semiconductor film extends in a stacking direction within a stacked body of a plurality of conductive layers with insulating layers therebetween, and neighboring parts of the conductive layers and the semiconductor film function as memory cells. It is desirable to improve operational reliability of this semiconductor memory device.

### DESCRIPTION OF THE DRAWINGS

FIG. 1 is a perspective view showing an overview configuration of a semiconductor memory device according to an embodiment.

FIG. 2 is a block diagram showing an overview configuration of the semiconductor memory device according to the embodiment.

FIG. 3 is a circuit diagram showing a configuration of a memory cell array in the embodiment.

FIG. 4 is a cross-sectional view showing the configuration of the memory cell array in the embodiment.

FIG. 5 is a plan view showing a configuration of a memory cell in the embodiment.

FIGS. 6A and 6B are enlarged cross-sectional views showing a configuration near the memory cell in the embodiment.

FIG. 7 is a cross-sectional view showing a configuration of a memory cell array in a first modification example of the embodiment.

FIGS. 8A to 8C are enlarged cross-sectional views showing a configuration near a memory cell in the first modification example of the embodiment.

FIGS. 9A and 9B are cross-sectional views showing a method of manufacturing a semiconductor memory device according to a second modification example of the embodiment.

FIGS. 10A and 10B are cross-sectional views showing the method of manufacturing the semiconductor memory device according to the second modification example of the embodiment.

FIGS. 11A to 11H are cross-sectional views showing a method of manufacturing the semiconductor memory device according to the second modification example of the embodiment.

FIGS. 12A to 12H are cross-sectional views showing the method of manufacturing the semiconductor memory device according to the second modification example of the embodiment.

FIGS. 13A to 13F are cross-sectional views showing the method of manufacturing the semiconductor memory device according to the second modification example of the embodiment.

### DETAILED DESCRIPTION

Embodiments provide a semiconductor memory device capable of improving operational reliability, and a method of manufacturing the semiconductor memory device.

In general, according to one embodiment, a semiconductor memory device including a stacked body, a semiconductor film, an insulating film, and a charge storage film is provided. The stacked body includes a first region and a second region. The second region is located above the first region in a stacking direction. In the stacked body, a plurality of first conductive layers are stacked via (e.g., stacked with) a first insulating layer in the first region. In the stacked body, a plurality of second conductive layers are stacked via a second insulating layer in the second region. The semiconductor film extends in the stacking direction in the first region and the second region. The charge storage film includes a plurality of first convex parts and a plurality of second convex parts. The plurality of first convex parts are disposed between the plurality of first conductive layers and the semiconductor film in the first region and are continuous with each other in the stacking direction. Each of the plurality of first convex parts protrudes toward the first conductive layer at a stacking position corresponding to the first conductive layer. The plurality of second convex parts are disposed between the plurality of second conductive layers and the semiconductor film in the second region and are separated from each other in the stacking direction. Each of the plurality of second convex parts protrudes toward the second conductive layer at a stacking position corresponding to the second conductive layer. A film thickness of the first insulating layer is larger than a film thickness of the second insulating layer.

A Semiconductor memory device according to an embodiment will be described in detail below with reference to the accompanying drawings. The present disclosure is not limited to the embodiment.

### Embodiment

A semiconductor memory device according to an embodiment has a three-dimensional structure in which a semiconductor film extends in a stacking direction within a stacked body of a plurality of conductive layers with insulating layers therebetween, and neighboring parts of the conductive layers and the semiconductor film function as memory cells, and is designed to improve its operational reliability.

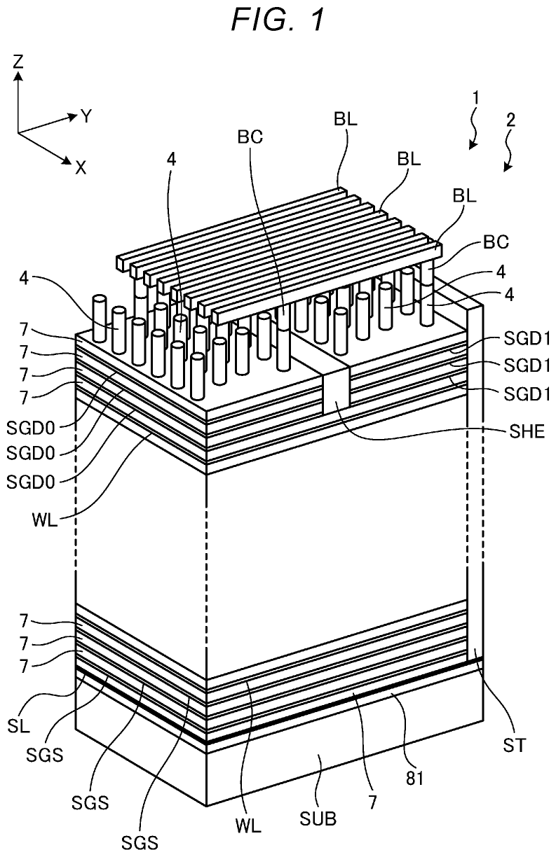

A semiconductor memory device 1 can be configured as shown in FIG. 1. FIG. 1 is a perspective view schematically showing a configuration of a memory cell array 2 provided in the semiconductor memory device 1 according to the embodiment. The semiconductor memory device 1 is a NAND-type nonvolatile memory including memory cells that are disposed three-dimensionally. In the following, a direction perpendicular to the surface of a substrate SUB is set to be a Z direction, and two directions orthogonal to each other in a plane perpendicular to the Z direction are set to be an X direction and a Y direction.

As shown in FIG. 1, the semiconductor memory device 1 includes a source line SL, select gates SGS, word lines WL, and select gates SGD. The source line SL is stacked on the +Z side of the substrate SUB via an interlayer insulating film 81. The select gate SGS is stacked on the source line SL via an insulating layer 7. In the example of FIG. 1, three layers of the select gates SGS are provided. The word line WL is stacked on the uppermost select gate SGS via the insulating layer 7. In the example of FIG. 1, a plurality of layers of word lines WL are provided. The select gate SGD is stacked on the uppermost word line WL via the insulating layer 7. In the example of FIG. 1, three layers of select gates SGD are provided. The select gates SGD mean a plurality of select gates that are provided in the same layer and are separated. In the example of FIG. 1, select gates SGD0 and SGD1 that are separated in the Y direction are shown. The select gate SGD is stacked on the uppermost word line WL via the insulating layer 7. The source line SL, the select gates SGS, the word lines WL, and the select gates SGD are plate-shaped extending in the X and Y directions.

In the example of FIG. 1, the select gates SGD, the word lines WL, and the select gates SGS are divided and insulated in the Y direction by a slit ST. The slit ST is provided in the substrate SUB and extends in the X and Z directions.

The select gate SGD is divided in the Y direction, for example, by an insulating film SHE. The insulating film SHE is provided above the word line WL (on the +Z side) and extends in the X and Z directions. For this reason, the select gates SGD0 and SGD1 are arranged side by side in the Y direction on the word line WL. In the example of FIG. 1, the select gates SGD0 and SGD1 are each provided in three layers.

The substrate SUB may be formed of a material containing a semiconductor, such as silicon, as a main component. The select gate SGS, the word line WL, and the select gate SGD may each be formed of a material containing a metal, such as tungsten (W), as a main component. The interlayer insulating film 7 and the insulating film SHE may each be formed of an insulator such as a silicon oxide.

The semiconductor memory device 1 further includes a plurality of columnar bodies 4. The columnar bodies 4 extend in the Z direction, which is the stacking direction, so as to penetrate the select gates SGS, the word lines WL, and the select gates SGD. The semiconductor memory device 1 further includes a plurality of bit lines BL provided above the select gate SGD.

Each of the columnar bodies 4 is electrically connected to the bit line BL via a contact plug BC. The contact plug BC is a contact plug for the bit line BL. FIG. 1 shows a configuration in which one of the columnar bodies 4 sharing the select gate SGD0 and one of the columnar bodies 4 sharing the select gate SGD1 are electrically connected to one bit line BL via the contact plug BC.

In the case of a semiconductor memory device (memory) having a three-dimensional structure such as the semiconductor memory device 1, an intersection portion between the word line WL and the columnar body 4 is configured to function as a memory cell, and the memory cell array 2 in which a plurality of memory cells are arranged three-dimensionally is configured. In addition, an intersection portion between the select gate SGS and the columnar body 4 functions as a source-side select gate, and an intersection portion between the select gates SGD0, SGD1 and the columnar body 4 functions as a drain-side select gate. In the semiconductor memory device 1, it is possible to increase storage capacity by increasing the number of stacked layers of the word lines WL in the stacked body without using finer patterning technology.

In FIG. 1, for simplicity of illustration, an interlayer insulating film provided between the select gate SGD and the bit line BL is not shown. Further, a configuration in which the substrate SUB is disposed on the opposite side to the bit line BL with respect to the memory cell array 2 is shown in FIG. 1, but the substrate SUB may be disposed on the opposite side of the memory cell array 2 with respect to the bit line BL.

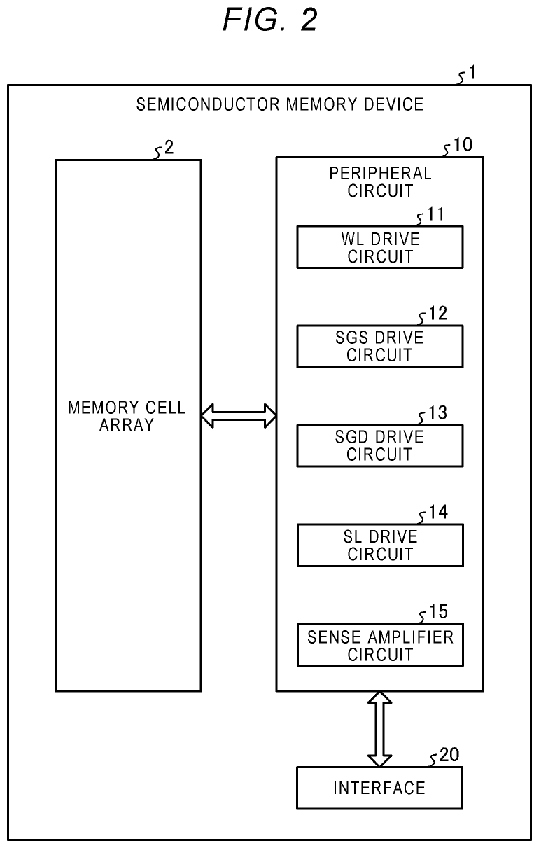

FIG. 2 is a block diagram showing the configuration of the semiconductor memory device 1.

As shown in FIG. 2, the semiconductor memory device 1 includes the memory cell array 2, a peripheral circuit 10, and an interface 20. The peripheral circuit 10 includes a WL drive circuit 11, an SGS drive circuit 12, an SGD drive circuit 13, an SL drive circuit 14, and a sense amplifier circuit 15.

The WL drive circuit 11 is a circuit that controls a voltage to be applied to the word line WL, and the SGS drive circuit 12 is a circuit that controls a voltage to be applied to the select gate SGS. The SGD drive circuit 13 is a circuit that controls a voltage to be applied to the select gate SGD, and the SL drive circuit 14 is a circuit that controls a voltage to be applied to the source line SL. The sense amplifier circuit 15 is a circuit that determines data that is read in response to a signal received from a selected memory cell.

The peripheral circuit 10 controls the operation of the semiconductor memory device 1 on the basis of an instruction that is input from the outside (for example, a memory controller of a memory system to which the semiconductor memory device 1 is applied) via the interface 20. For example, when the peripheral circuit 10 receives a write instruction, the peripheral circuit 10 selects a memory cell of an address to which the write instruction is given by the SGS drive circuit 12, the SGD drive circuit 13, and the WL drive circuit 11, and applies a voltage corresponding to data to write the data to the selected memory cell. In addition, when the peripheral circuit 10 receives a read instruction, the peripheral circuit 10 selects a memory cell of an indicated address in the memory cell array 2 by the SGS drive circuit 12, the SGD drive circuit 13, and the WL drive circuit 11, determines data that is read in response to a signal received from the selected memory cell by the sense amplifier circuit 15, and outputs the data to the outside (memory controller) via the interface 20.

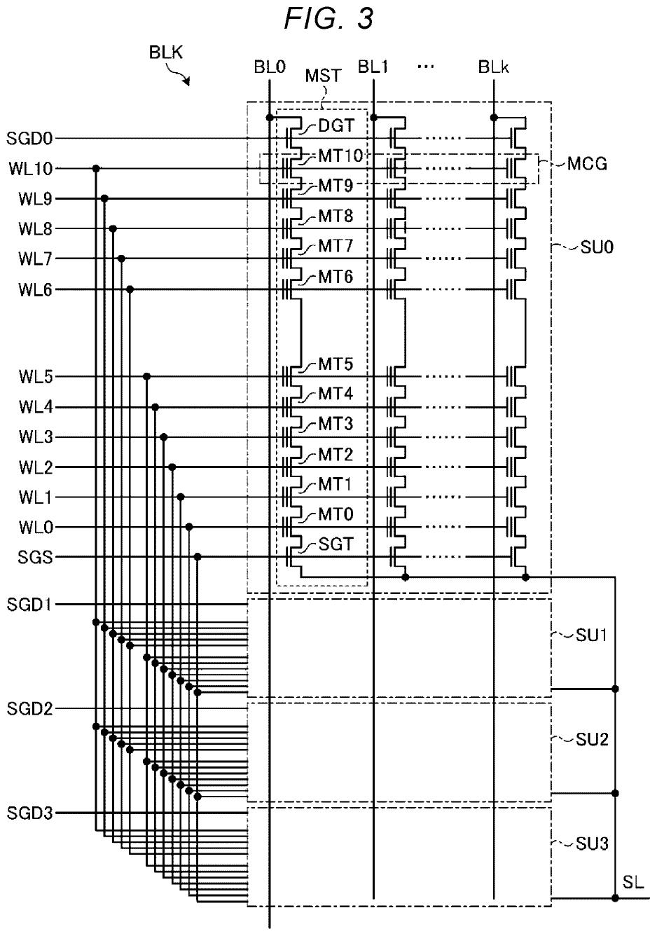

Next, the configuration of the memory cell array 2 will be described using FIG. 3. FIG. 3 is a circuit diagram showing the configuration of the memory cell array 2 provided in the semiconductor memory device 1.

The memory cell array 2 includes a plurality of blocks BLK, each of which is a collection of a plurality of memory cells MT. The memory cells MT are also referred to as memory cell transistors.

Each of the blocks BLK includes a plurality of string units SU0, SU1, SU2, and SU3 each of which is a collection of memory cells MT associated with the word lines WL and the bit lines BL. Each of the string units SU0 to SU3 includes a plurality of memory strings MST in which the memory cells MT are connected in series. The number of memory strings MST in each of the string units SU0 to SU3 is freely selected.

The plurality of string units SU0, SU1, SU2, and SU3 correspond to the plurality of select gate lines SGD0, SGD1, SGD2, and SGD3, and share the select gate lines SGS, and function as a plurality of drive units in the block BLK. Each string unit SU can be driven by its corresponding select gate line SGD and select gate line SGS. Each string unit SU also includes a plurality of memory strings MST.

Each memory string MST includes, for example, 11 memory cells MT (MT0 to MT10) and select transistors DGT and SGT. The memory cell MT includes a control gate and a charge storage layer, and stores data in a non-volatile manner. The 11 memory cells MT (MT0 to MT10) are connected in series between a source of the select transistor DGT and a drain of the select transistor SGT. The number of memory cells MT in the memory string MST is not limited to 11.

Gates of select transistors DGT in each string unit SU are connected to the select gate lines SGD. Meanwhile, gates of select transistors SGT in each string unit SU are connected in common to, for example, the select gate line SGS.

Drains of select transistors DGT of each memory string MST in each string unit SU are connected to different bit lines BL0 to BLk (k is any integer equal to or greater than 2). The bit lines BL0 to BLk also connect one memory string MST in each string unit SU in common between the plurality of blocks BLK. Furthermore, sources of the select transistors SGT are connected in common to the source line SL.

That is, the string unit SU is a collection of memory strings MST that are connected to different bit lines BL0 to BLk and the same select gate line SGD. In addition, the block BLK is a collection of the plurality of string units SU0 to SU3 that share the word lines WL. The memory cell array 2 is a collection of the plurality of blocks BLK that share the bit lines BL0 to BLk.

When a group of memory cells MT that share the word lines WL is referred to as a “memory cell group MCG”, the memory cell group MCG is the smallest unit of a collection of memory cells to which a predetermined voltage (for example, a write voltage, a read voltage) can be applied collectively via the word lines WL.

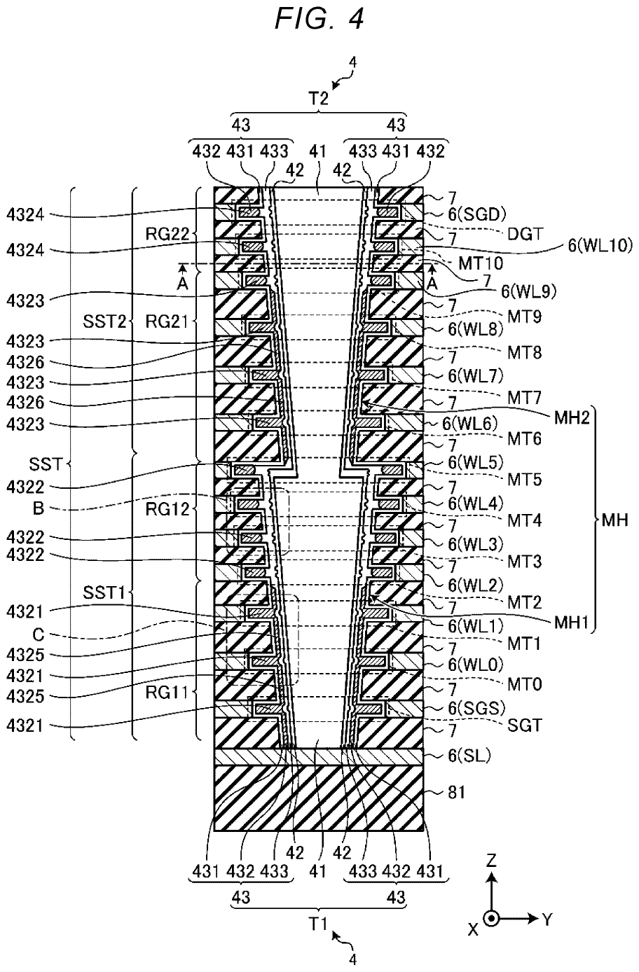

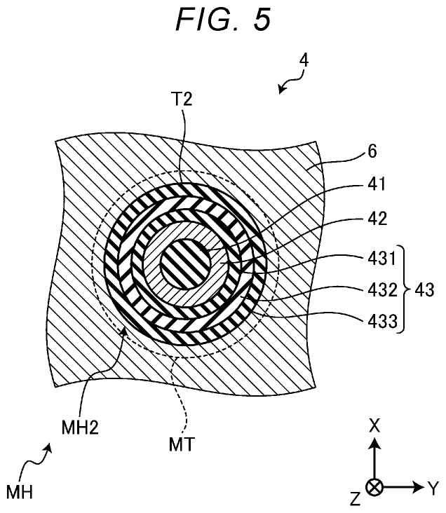

Next, a specific configuration of the memory cell array 2 will be described using FIGS. 4 and 5. FIG. 4 is a ZY cross-sectional view showing the configuration of the memory cell array 2. FIG. 5 is an XY plan view showing the configuration of the memory cell MT, showing the XY plane when FIG. 4 is cut along a line A-A.

As shown in FIGS. 1, 4 and 5, the memory cell array 2 is configured as a three-dimensional array of memory cells MT on the +Z side of the substrate SUB and configured such that the columnar bodies 4 are arranged two-dimensionally in the XY direction and penetrate a plurality of layers of word lines WL.

In the memory cell array 2, a stacked body SST is formed such that conductive layers 6 and insulating layers 7 are alternately and repeatedly stacked. In the stacked body SST, each conductive layer 6 can be formed of a material containing a conductive material (for example, a metal such as tungsten) as a main component. Each insulating layer 7 can be formed of a material containing an insulating material (for example, a semiconductor oxide such as a silicon oxide) as a main component. Most of the conductive layers 6 function as the word lines WL. The conductive layer 6 on the +Z side functions as the select gate line SGD. The conductive layer 6 on the −Z side functions as the select gate line SGS.

A plurality of memory holes MH (see FIG. 4) are formed in the stacked body SST. The memory holes MH extend in the Z direction in the stacked body SST. The memory holes MH may penetrate the stacked body SST in the Z direction. The plurality of memory holes MH are arranged two-dimensionally in the XY direction. The columnar body 4 is disposed in each memory hole MH. Thereby, a two-dimensional array of a plurality of columnar bodies 4 corresponding to the plurality of memory holes MH is configured.

In the memory cell array 2, a plurality of memory cells MT are configured at a plurality of positions where the plurality of word lines WL and the plurality of columnar bodies 4 intersect each other. A plurality of select transistors DGT are formed at a plurality of positions where the select gate lines SGD and the plurality of columnar bodies 4 intersect each other. A plurality of select transistors SGT are formed at a plurality of positions where the select gate lines SGS and the plurality of columnar bodies 4 intersect each other. As shown in FIG. 5, the columnar body 4 includes a core insulating film 41, a semiconductor film 42, and an insulating film 43. The core insulating film 41, the semiconductor film 42, and the insulating film 43 are disposed in the memory hole MH. The core insulating film 41 may be formed of a material containing an insulating material (for example, a silicon oxide) as a main component. The core insulating film 41 has a substantially cylindrical shape extending along the central axis of the columnar body 4. The semiconductor film 42 is disposed to surround the core insulating film 41 from the outside and has a substantially cylindrical shape extending along the central axis of the columnar body 4. The insulating film 43 is disposed to surround the semiconductor film 42 from the outside and has a substantially cylindrical shape extending along the central axis of the columnar body 4.

The semiconductor film 42 includes a channel region (active region) in the memory string MST, and can be formed of a material containing a semiconductor (for example, polysilicon) as a main component.

The insulating film 43 is disposed between the conductive layer 6 and the semiconductor film 42, and surrounds the semiconductor film 42 in a plan view. The insulating film 43 covers the side surface of the semiconductor film 42. The insulating film 43 is configured to have charge storage capability in a portion disposed between the conductive layer 6 and the semiconductor film 42.

As shown in FIG. 5, the insulating film 43 may be configured as a three-layer structure including a tunnel insulating film 431, a charge storage film 432, and a block insulating film 433 in this order from the semiconductor film 42 side. That is, the core insulating film 41, the semiconductor film 42, the tunnel insulating film 431, the charge storage film 432, and the block insulating film 433 may be disposed in the memory hole MH in this order from the center side. The tunnel insulating film 431 may be formed of a material containing an oxide (for example, a silicon oxide) as a main component. The charge storage film 432 may be formed of a material containing a nitride (for example, a silicon nitride) as a main component. The block insulating film 433 may be formed of a material containing an oxide (for example, a silicon oxide, a metal oxide, or a stacked layer thereof) as a main component.

That is, the insulating film 43 may have an ONO-type three-layer structure in which the charge storage film is sandwiched between a pair of insulating films (tunnel insulating film, block insulating film) in a portion (memory cell MT) disposed between the conductive layer 6 (word line WL) and the semiconductor film 42. In addition, the insulating film 43 may be configured as a single-layer structure of a gate insulating film in a portion (select transistor DGT) disposed between the conductive layer 6 (select gate line SGD) and the semiconductor film 42. The gate insulating film may be formed of a material containing oxide (for example, a silicon oxide) as a main component.

In the semiconductor memory device 1, when the number of stacked layers of the conductive layer 6 is increased, an aspect ratio (=(dimension in the stacking direction)/(dimension in the plane direction)) of the columnar body 4 will increase, resulting in a possibility that processing may become more difficult.

In response to this, it is conceivable that the columnar body 4 penetrating the stacked body SST has a structure in which a plurality of tiers are stacked. For example, the stacked body SST is divided into a plurality of stacked bodies corresponding to the plurality of tiers, and the memory hole MH having the columnar body 4 embedded therein is divided into a plurality of memory holes accordingly. Since the aspect ratio of each of the plurality of memory holes is lower than the aspect ratio of the memory hole MH before division, the difficulty of processing can be lowered.

Regarding the memory holes MH shown in FIG. 4, the memory hole MH1 and the memory hole MH2 are stacked in this order. In each columnar body 4, a tier T1 and a tier T2 are stacked in this order. Regarding the stacked bodies SST, a stacked body SST1 and a stacked body SST2 are stacked in this order.

The stacked body SST1 includes a region RG11 and a region RG12. The region RG12 is located on the +Z side of the region RG11. The memory hole MH1 extends in the Z direction in the stacked body SST1. The memory hole MH1 may penetrate the stacked body SST1 in the Z direction. The tier T1 is disposed in the memory hole MH1. The tier T1 extends in the Z direction in the stacked body SST1. The tier T1 may penetrate the stacked body SST1 in the Z direction.

An average plane width of the memory hole MH1 in the region RG11 is smaller than an average plane width of the memory hole MH1 in the region RG12. The average plane width is obtained by averaging the maximum dimension in the XY direction in the Z direction within a predetermined region. When the memory hole MH1 has a substantially cylindrical shape, an average plane width of the memory hole MH1 in the region RG11 is obtained by averaging the diameter of the memory hole MH1 in the Z direction within the region RG11. An average plane width of the memory hole MH1 in the region RG12 is obtained by averaging the diameter of the memory hole MH1 in the Z direction within the region RG12. When the memory hole MH1 has a substantially prismatic shape, an average plane width of the memory hole MH1 in the region RG11 is obtained by averaging a diagonal length of a rectangular cross section of the memory hole MH1 in the Z direction within the region RG11. An average plane width of the memory hole MH1 in the region RG12 is obtained by averaging a diagonal length of a rectangular cross section of the memory hole MH1 in the Z direction within the region RG12.

Accordingly, an average plane width of the tier T1 in the region RG11 is smaller than an average plane width of the tier T1 in the region RG12.

In the stacked body SST1, the conductive layer 6 (select gate line SGS), the conductive layer 6 (word line WL0), the conductive layer 6 (word line WL1), the conductive layer 6 (word line WL2) are stacked via the insulating layer 7 in the region RG11.

In the region RG11, portions where the conductive layer 6 (select gate line SGS), the conductive layer 6 (word line WL0), the conductive layer 6 (word line WL1), and the conductive layer 6 (word line WL2) intersect the tier T1 function as the select transistor SGT, the memory cell MT0, the memory cell MT1, and the memory cell MT2, respectively.

The charge storage film 432 of the tier T1 includes a plurality of convex parts 4321 and connection parts 4325 in the region RG11. The plurality of convex parts 4321 are disposed between the plurality of conductive layers 6 and the semiconductor film 42 in the region RG11. The plurality of convex parts 4321 are continuous with each other in the Z direction via the connection parts 4325. The connection parts 4325 cover the inner surface of the memory hole MH1 and connect the plurality of convex parts 4321 adjacent to each other in the Z direction.

The plurality of convex parts 4321 correspond to the conductive layer 6 (select gate line SGS), the conductive layer 6 (word line WL0), the conductive layer 6 (word line WL1), and the conductive layer 6 (word line WL2). Each convex part 4321 protrudes toward the corresponding conductive layer 6 at the Z position of the corresponding conductive layer 6.

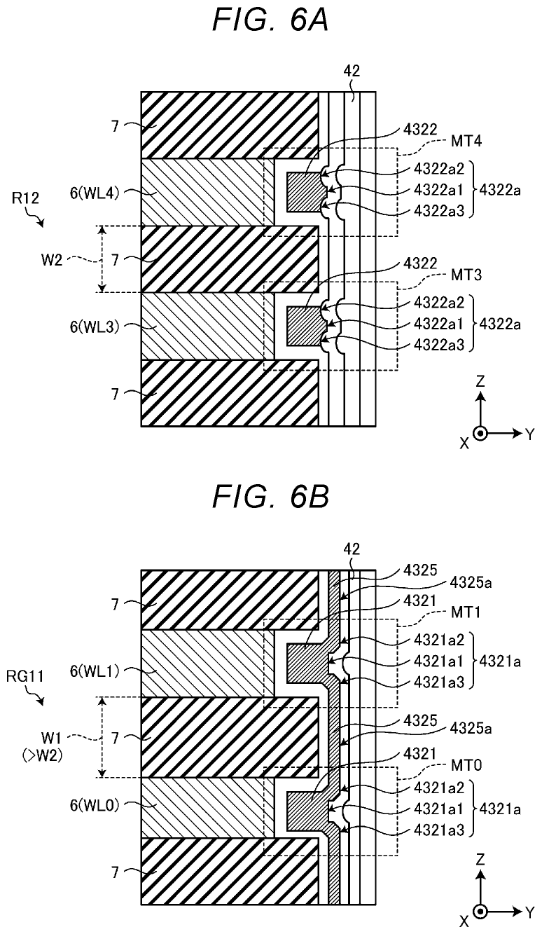

As shown in FIG. 6B, in each convex part 4321, a surface 4321a on the semiconductor film side includes a concave surface 4321a1 in the central part in the Z direction. FIGS. 6A and 6B are enlarged cross-sectional views showing a configuration near the memory cell MT. FIG. 6B is an enlarged cross-sectional view of a C portion in FIG. 4.

In the convex part 4321 of the memory cell MT0, the surface 4321a on the semiconductor film side includes the concave surface 4321a1, a flat surface 4321a2, and a flat surface 4321a3.

The flat surface 4321a2 is located on the +Z side of the surface 4321a. The flat surface 4321a2 is substantially flat. The flat surface 4321a2 is continuous with a surface 4325a of the connection part 4325 on the semiconductor film side on the +Z side. The surface 4325a is substantially flat.

The flat surface 4321a3 is located on the −Z side of the surface 4321a. The flat surface 4321a3 is substantially flat. The flat surface 4321a3 is continuous with the surface 4325a of the connection part 4325 on the semiconductor film side on the −Z side. The surface 4325a is substantially flat.

The concave surface 4321a1 is located at the central part of the surface 4321a in the Z direction. The concave surface 4321a1 is disposed between the flat surface 4321a2 and the flat surface 4321a3 in the Z direction. The concave surface 4321a1 is recessed toward the conductive layer 6 (word line WL0) from each of the flat surface 4321a2 and the flat surface 4321a3. The concave surface 4321a1 may be recessed in a curved shape toward the conductive layer 6 (word line WL0).

The convex part 4321 in the memory cell MT1 is the same as the convex part 4321 in the memory cell MT0.

The select transistor SGT, the memory cell MT0, the memory cell MT1, and the memory cell MT2 in the region RG11 can store charges in the convex part 4321.

In the stacked body SST1, the conductive layer 6 (word line WL2), the conductive layer 6 (word line WL3), the conductive layer 6 (word line WL4), and the conductive layer 6(word line WL5) are stacked via the insulating layer 7 in the region RG12.

In the region RG12, portions where the conductive layer 6 (word line WL2), the conductive layer 6 (word line WL3), the conductive layer 6 (word line WL4), and the conductive layer 6 (word line WL5) intersect the tier T1 function as the memory cell MT2, the memory cell MT3, the memory cell MT4, and the memory cell MT5, respectively.

The charge storage film 432 of the tier T1 includes a plurality of convex parts 4322 in the region RG12. The plurality of convex parts 4322 are disposed between the plurality of conductive layers 6 and the semiconductor film 42 in the region RG12. The plurality of convex parts 4322 are separated from each other in the Z direction.

The plurality of convex parts 4322 correspond to the conductive layer 6 (word line WL2), the conductive layer 6 (word line WL3), the conductive layer 6 (word line WL4), and the conductive layer 6 (word line WL5). Each convex part 4322 protrudes toward the corresponding conductive layer 6 at the Z position of the corresponding conductive layer 6.

As shown in FIG. 6A, in each convex part 4322, a surface 4322a on the semiconductor film 42 side includes concave surfaces 4322a2 and 4322a3 at both ends in the Z direction. FIG. 6A is an enlarged cross-sectional view of a B portion in FIG. 4.

In the convex part 4322 in the memory cell MT3, the surface 4322a on the semiconductor film side includes a flat surface 4322a1, a concave surface 4322a2, and a concave surface 4322a3.

The flat surface 4322a1 is located at the central part of the surface 4322a in the Z direction. The flat surface 4322a1 is disposed between the concave surface 4322a2 and the concave surface 4322a3 in the Z direction. The flat surface 4322a1 is substantially flat.

The concave surface 4322a2 is located on the +Z side of the surface 4322a. The concave surface 4322a2 is recessed toward the conductive layer 6 (word line WL3) from the flat surface 4322a1. The concave surface 4322a2 may be recessed in a curved shape toward the conductive layer 6 (word line WL3).

The concave surface 4322a3 is located on the −Z side of the surface 4322a. The concave surface 4322a3 is recessed toward the conductive layer 6 (word line WL3) from the flat surface 4322a1. The concave surface 4322a3 may be recessed in a curved shape toward the conductive layer 6 (word line WL3).

The convex part 4322 in the memory cell MT4 is the same as the convex part 4322 in the memory cell MT3.

The memory cells MT2, MT3, MT4, and MT5 in the region RG12 can store charges in the convex part 4322.

Here, the plurality of convex parts 4321 in the region RG11 are continuous with each other in the Z direction via the connection parts 4325, and the plurality of convex parts 4322 in the region RG12 are separated from each other in the Z direction. For this reason, there is a possibility that the select transistor SGT, the memory cell MT0, the memory cell MT1, and the memory cell MT2 in the region RG11 will be more susceptible to charge leakage in the Z direction than the memory cell MT2, the memory cell MT3, the memory cell MT4, and the memory cell MT5 in the region RG12. That is, there is a possibility that the select transistor SGT, the memory cell MT0, the memory cell MT1, and the memory cell MT2 in the region RG11 will have lower information retention characteristics than the memory cell MT2, the memory cell MT3, the memory cell MT4, and the memory cell MT5 in the region RG12.

Meanwhile, as shown in FIGS. 6A and 6B, a film thickness W1 of the insulating layer 7 in the region RG11 is larger than a film thickness W2 of the insulating layer 7 in the region RG12. Accordingly, a Z-distance of the convex part 4321 in the region RG11 can be made larger than a Z-distance of the convex part 4322 in the region RG12. Thereby, it is possible to curb charge leakage in the Z direction in the select transistor SGT, the memory cell MT0, the memory cell MT1, and the memory cell MT2 in the region RG11. That is, the information retention characteristics of the select transistor SGT, the memory cell MT0, the memory cell MT1, and the memory cell MT2 in the region RG11 can be made closer to the information retention characteristics of the memory cell MT2, the memory cell MT3, the memory cell MT4, and the memory cell MT5 in the region RG12.

The stacked body SST2 includes a region RG21 and a region RG22. The region RG22 is located on the +Z side of the region RG21. The memory hole MH2 extends in the Z direction in the stacked body SST2. The memory hole MH2 may penetrate the stacked body SST2 in the Z direction. The tier T2 is disposed in the memory hole MH2. The tier T2 extends in the Z direction in the stacked body SST2. The tier T2 may penetrate the stacked body SST2 in the Z direction.

An average plane width of the memory hole MH2 in the region RG21 is smaller than an average plane width of the memory hole MH2 in the region RG22. An average plane width of the tier T2 in the region RG21 is smaller than an average plane width of the tier T2 in the region RG22.

In the stacked body SST2, the conductive layer 6 (word line WL6), the conductive layer 6 (word line WL7), and the conductive layer 6 (word line WL8) are stacked via the insulating layer 7 in the region RG21.

The charge storage film 432 of the tier T2 includes a plurality of convex parts 4323 and connection parts 4325 in the region RG21. The plurality of convex parts 4323 are disposed between the plurality of conductive layers 6 and the semiconductor film 42 in the region RG21. The plurality of convex parts 4323 are continuous with each other in the Z direction via the connection parts 4325. The connection parts 4325 cover the inner surface of the memory hole MH2 and connect the plurality of convex parts 4323 adjacent to each other in the Z direction.

The plurality of convex parts 4323 correspond to the conductive layer 6 (word line WL6), the conductive layer 6 (word line WL7), and the conductive layer 6 (word line WL8). Each convex part 4323 protrudes toward the corresponding conductive layer 6 at the Z position of the corresponding conductive layer 6.

In each convex part 4323, a surface 4323a on the semiconductor film side includes a concave surface 4323a1 in the central part in the Z direction (see FIG. 6B).

In the convex part 4323 in the memory cell MT6, the surface 4323a on the semiconductor film side includes the concave surface 4323a1, a flat surface 4323a2, and a flat surface 4323a3.

The flat surface 4323a2 is located on the +Z side of the surface 4323a. The flat surface 4323a2 is substantially flat. The flat surface 4323a2 is continuous with the surface 4325a of the connection part 4325 on the semiconductor film side on the +Z side. The surface 4325a is substantially flat.

The flat surface 4323a3 is located on the −Z side of the surface 4323a. The flat surface 4323a3 is substantially flat. The flat surface 4323a3 is continuous with the surface 4325a of the connection part 4325 on the semiconductor film side on the −Z side. The surface 4325a is substantially flat.

The concave surface 4323a1 is located at the central part of the surface 4323a in the Z direction. The concave surface 4323a1 is disposed between the flat surface 4323a2 and the flat surface 4323a3 in the Z direction. The concave surface 4323a1 is recessed toward the conductive layer 6 (word line WL6) from each of the flat surface 4323a2 and the flat surface 4323a3. The concave surface 4323a1 may be recessed in a curved shape toward the conductive layer 6 (word line WL6).

The convex part 4323 in the memory cell MT7 is the same as the convex part 4323 in the memory cell MT6.

The memory cell MT6, the memory cell MT7, and the memory cell MT8 in the region RG21 can store charges in the convex part 4323.

In the stacked body SST2, the conductive layer 6 (word line WL9), the conductive layer 6 (word line WL10), and the conductive layer 6 (select gate line SGD) are stacked via the insulating layer 7 in the region RG22.

The charge storage film 432 of the tier T2 includes a plurality of convex parts 4324 in the region RG22. The plurality of convex parts 4324 are disposed between the plurality of conductive layers 6 and the semiconductor film 42 in the region RG22. The plurality of convex parts 4324 are separated from each other in the Z direction.

The plurality of convex parts 4324 correspond to the conductive layer 6 (word line WL9), the conductive layer 6 (word line WL10), and the conductive layer 6 (select gate line SGD). Each convex part 4324 protrudes toward the corresponding conductive layer 6 at the Z position of the corresponding conductive layer 6.

In each convex part 4324, a surface 4324a on the semiconductor film 42 side includes concave surfaces 4324a2 and 4324a3 at both ends in the Z direction (see FIG. 6A).

In the convex part 4324 in the memory cell MT9, the surface 4324a on the semiconductor film side includes a flat surface 4324a1, a concave surface 4324a2, and a concave surface 4324a3.

The flat surface 4324a1 is located at the central part of the surface 4324a in the Z direction. The flat surface 4324a1 is disposed between the concave surface 4324a2 and the concave surface 4324a3 in the Z direction. The flat surface 4324a1 is substantially flat.

The concave surface 4324a2 is located on the +Z side of the surface 4324a. The concave surface 4324a2 is recessed toward the conductive layer 6 (word line WL9) from the flat surface 4324a1. The concave surface 4324a2 may be recessed in a curved shape toward the conductive layer 6 (word line WL9).

The concave surface 4324a3 is located on the −Z side of the surface 4324a. The concave surface 4324a3 is recessed toward the conductive layer 6 (word line WL9) from the flat surface 4324a1. The concave surface 4324a3 may be recessed in a curved shape toward the conductive layer 6 (word line WL9).

The convex part 4324 in the memory cell MT10 is the same as the convex part 4324 in the memory cell MT9.

The memory cell MT9, the memory cell MT10, and the select transistor DGT in the region RG22 can store charges in the convex part 4324.

Here, the plurality of convex parts 4323 in the region RG21 are continuous with each other in the Z direction via the connection parts 4326, and the plurality of convex parts 4324 in the region RG22 are separated from each other in the Z direction. For this reason, there is a possibility that the memory cell MT6, the memory cell MT7, and the memory cell MT8 in the region RG21 will be more susceptible to charge leakage in the Z direction than the memory cell MT9, the memory cell MT10, and the select transistor DGT in the region RG22. That is, there is a possibility that the memory cell MT6, the memory cell MT7, and the memory cell MT8 in the region RG21 will have lower information retention characteristics than the memory cell MT9, the memory cell MT10, and the select transistor DGT in the region RG22.

Meanwhile, a film thickness W1 of the insulating layer 7 in the region RG21 is larger than a film thickness W2 of the insulating layer 7 in the region RG22 (see FIGS. 6A and 6B). Accordingly, a Z-distance of the convex part 4323 in the region RG21 can be made larger than a Z-distance of the convex part 4324 in the region RG22. Thereby, it is possible to curb charge leakage in the Z direction in the memory cell MT6, the memory cell MT7, and the memory cell MT8 in the region RG21. That is, the information retention characteristics of the memory cell MT6, the memory cell MT7, and the memory cell MT8 in the region RG21 can be made closer to the information retention characteristics of the memory cell MT9, the memory cell MT10, and the select transistor DGT in the region RG22.

As described above, in this embodiment, in the semiconductor memory device 1, the film thickness W1 of the insulating layer 7 in the regions RG11 and R21 where the convex parts 4321 and 4323 are continuous in the Z direction is larger than the film thickness W2 of the insulating layer 7 in the regions RG12 and R22 where the convex parts 4322 and 4324 are divided in the Z direction. Thereby, it is possible to make the information retention characteristics of the memory cell MT6, the memory cell MT7, and the memory cell MT8 in the region RG21 closer to the information retention characteristics of the memory cell MT9, the memory cell MT10, and the select transistor DGT in the region RG22. That is, it is possible to equalize the information retention characteristics between the plurality of memory cells MT and the select transistors lined up in the Z direction and to improve the operational reliability of the semiconductor memory device 1.

As a first modification example of the embodiment, in a semiconductor memory device 1i, the film thickness of an insulating layer 7i in each of stacked bodies SST1i and SST2i of a stacked body SSTi may change in a multi-stage manner (e.g., stepwise manner). As the film thickness of the charge storage film 432 increases from the +Z side (e.g., upper side) to the −Z side (e.g., lower side) of each of the stacked bodies SST1i and SST2i, the film thickness of the insulating layer 7i may increase in a multi-stage manner. That is, the configuration shown in FIG. 4 may be modified such that the film thickness of the insulating layer 7 in each of the regions RG11 and RG21 is increased in two stages or three or more stages from the +Z side to the −Z side.

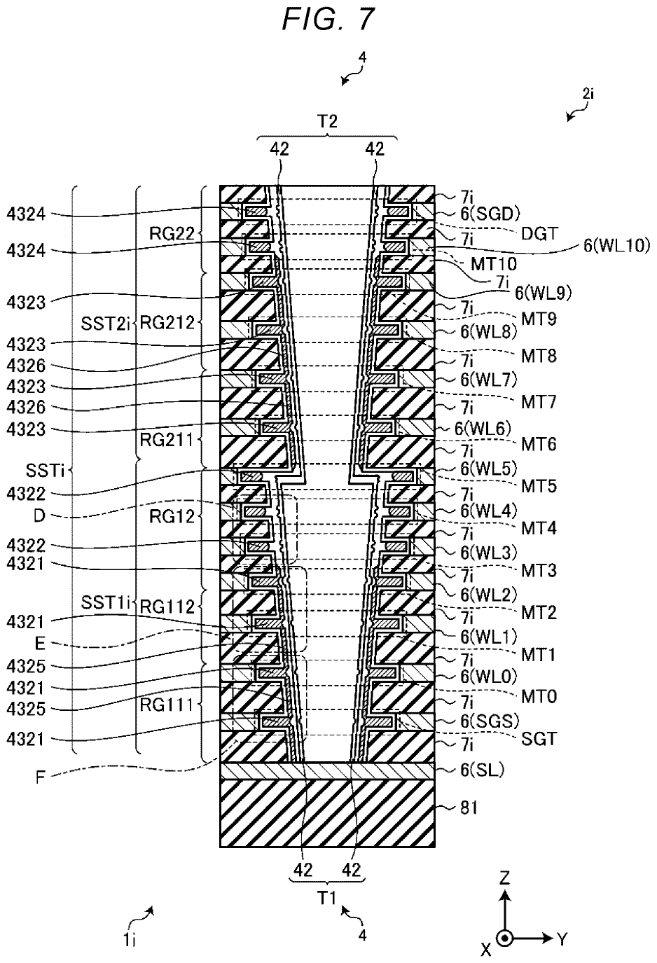

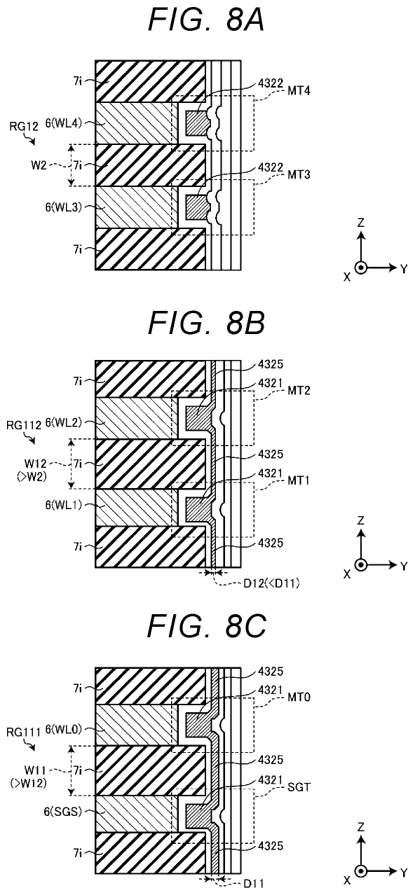

For example, when a change is made such that the film thickness is increased in two stages, a memory cell array 2i may be configured as shown in FIGS. 7 and 8. FIG. 7 is a YZ cross-sectional view showing the configuration of the memory cell array 2i in the first modification example of the embodiment. FIGS. 8A to 8C are enlarged YZ cross-sectional views showing a configuration near a memory cell MT in the first modification example of the embodiment. FIGS. 8A, 8B and 8C are enlarged YZ cross-sectional views of a D portion, an E portion, and an F portion in FIG. 7, respectively.

The stacked body SST1i includes a region RG111 and a region RG112 instead of the region RG11 (see FIG. 4). The region RG111 and the region RG112 are equivalent to regions obtained by dividing the region RG11 into two parts. The region RG112 is located on the +Z side of the region RG111. A region RG12 is located on the +Z side of the region RG112.

An average plane width of a memory hole MH1 in the region RG111 is smaller than an average plane width of a memory hole MH1 in the region RG112. An average plane width of a tier T1 in the region RG111 is smaller than an average plane width of a tier T1 in the region RG112.

An average plane width of the memory hole MH1 in the region RG112 is smaller than an average plane width of the memory hole MH1 in the region RG12. An average plane width of a tier T1 in the region RG111 is smaller than an average plane width of the tier T1 in the region RG112.

A select transistor SGT and a memory cell MT0 in the region RG111 can store charges in a convex part 4321.

A memory cell MT1 and a memory cell MT2 in the region RG112 can store charges in the convex part 4321.

The memory cell MT2, a memory cell MT3, a memory cell MT4, and a memory cell MT5 in the region RG12 can store charges in a convex part 4322.

Here, as shown in FIGS. 8B and 8C, a film thickness D12 of a connection part 4325 in the region RG112 is smaller than a film thickness D11 of the connection part 4325 in the region RG111. For this reason, there is a possibility that the memory cell MT1 and the memory cell MT2 in the region RG112 will be less susceptible to charge leakage in the Z direction than the select transistor SGT and the memory cell MT0 in the region RG111. That is, there is a possibility that the memory cell MT1 and the memory cell MT2 in the region RG112 will have higher information retention characteristics than the select transistor SGT and the memory cell MT0 in the region RG111.

Meanwhile, the plurality of convex parts 4321 in the region RG112 are continuous with each other in the Z direction via the connection parts 4325, and the plurality of convex parts 4322 in the region RG12 are separated from each other in the Z direction. For this reason, there is a possibility that the memory cell MT1 and the memory cell MT2 in the region RG112 will be more susceptible to charge leakage in the Z direction than the memory cell MT2, the memory cell MT3, the memory cell MT4, and the memory cell MT5 in the region RG12. That is, there is a possibility that the memory cell MT1 and the memory cell MT2 in the region RG112 will have lower information retention characteristics than the memory cell MT2, the memory cell MT3, the memory cell MT4, and the memory cell MT5 in the region RG12.

Meanwhile, as shown in FIGS. 8A to 8C, a film thickness W12 of the insulating layer 7i in the region RG112 is larger than a film thickness W2 of the insulating layer 7i in the region RG12 and is smaller than the film thickness of the insulating layer 7i in the region RG111. Accordingly, a Z-distance of the convex part 4321 in the region RG112 can be made larger than a Z-distance of the convex part 4322 in the region RG12 and smaller than a Z-distance of the convex part 4321 in the region RG111. Thereby, it is possible to curb charge leakage in the Z direction in the memory cell MT1 and the memory cell MT2 in the region RG112 to the same extent as in the region RG111. That is, the information retention characteristics of the memory cell MT1 and the memory cell MT2 in region RG112 can be made closer to the information retention characteristics of the memory cell MT2, the memory cell MT3, the memory cell MT4, and the memory cell MT5 in the region RG12, and can be made closer to the information retention characteristics of the select transistor SGT and the memory cell MT0 in the region RG111.

The stacked body SST2i includes a region RG211 and a region RG212 instead of the region RG21 (see FIG. 4). The region RG211 and the region RG212 are equivalent to regions obtained by dividing the region RG21 into two parts. The region RG212 is located on the +Z side of the region RG211. A region RG22 is located on the +Z side of the region RG212.

An average plane width of a memory hole MH2 in the region RG211 is smaller than an average plane width of the memory hole MH2 in the region RG212. An average plane width of a tier T2 in the region RG211 is smaller than an average plane width of a tier T2 in the region RG212.

An average plane width of the memory hole MH2 in the region RG212 is smaller than an average plane width of the memory hole MH2 in the region RG22. An average plane width of a tier T2 in the region RG211 is smaller than an average plane width of a tier T2 in the region RG212.

A memory cell MT6 and a memory cell MT7 in the region RG211 can store charges in a convex part 4323.

A memory cell MT8 and a memory cell MT9 in the region RG212 can store charges in the convex part 4323.

A memory cell MT10 and a select transistor DGT in the region RG22 can store charges in a convex part 4324.

Here, a film thickness D12 of a connection part 4326 in the region RG212 is smaller than a film thickness D11 of the connection part 4326 in the region RG211 (see FIGS. 8B and 8C). For this reason, there is a possibility that the memory cell MT8 and the memory cell MT9 in the region RG212 will be less susceptible to charge leakage in the Z direction than the memory cell MT6 and the memory cell MT7 in the region RG211. That is, there is a possibility that the memory cell MT8 and the memory cell MT9 in the region RG212 will have higher information retention characteristics than the memory cell MT6 and the memory cell MT7 in the region RG211.

Meanwhile, the plurality of convex parts 4323 in the region RG212 are continuous with each other in the Z direction via the connection parts 4326, and the plurality of convex parts 4324 in the region RG22 are separated from each other in the Z direction. For this reason, there is a possibility that the memory cell MT8 and the memory cell MT9 in the region RG212 will be more susceptible to charge leakage in the Z direction than the memory cell MT10 and the select transistor DGT in the region RG22. That is, there is a possibility that the memory cell MT8 and the memory cell MT9 in the region RG212 will have lower information retention characteristics than the memory cell MT10 and the select transistor DGT in the region RG22.

Meanwhile, a film thickness W12 of the insulating layer 7i in the region RG212 is larger than a film thickness W2 of the insulating layer 7i in the region RG22 and is smaller than the film thickness of the insulating layer 7i in the region RG211 (see FIGS. 8A to 8C). Accordingly, a Z-distance of the convex part 4323 in the region RG212 can be made larger than a Z-distance of the convex part 4324 in the region RG22 and smaller than a Z-distance of the convex part 4323 in the region RG211. Thereby, it is possible to curb charge leakage in the Z direction in the memory cell MT8 and the memory cell MT9 in the region RG212 to the same extent as in the region RG211. That is, the information retention characteristics of the memory cell MT8 and the memory cell MT9 in the region RG212 can be made closer to the information retention characteristics of the memory cell MT10 and the select transistor DGT in the region RG22, and can be made closer to the information retention characteristics of the memory cell MT6 and the memory cell MT7 in the region RG211.

In this manner, in the semiconductor memory device 1i, the film thickness of the insulating layer 7i in each of the stacked bodies SST1i and SST2i of the stacked body SSTi changes in a multi-stage manner. Thereby, it is possible to further equalize the information retention characteristics between the plurality of memory cells MT and the select transistors lined up in the Z direction and to further improve the operational reliability of the semiconductor memory device 1.

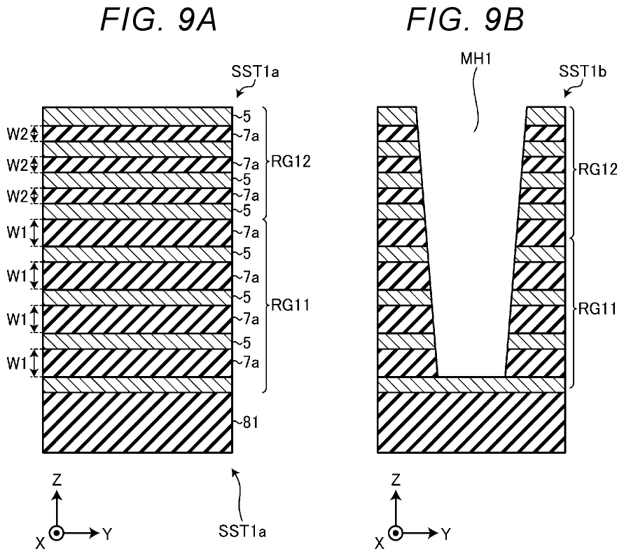

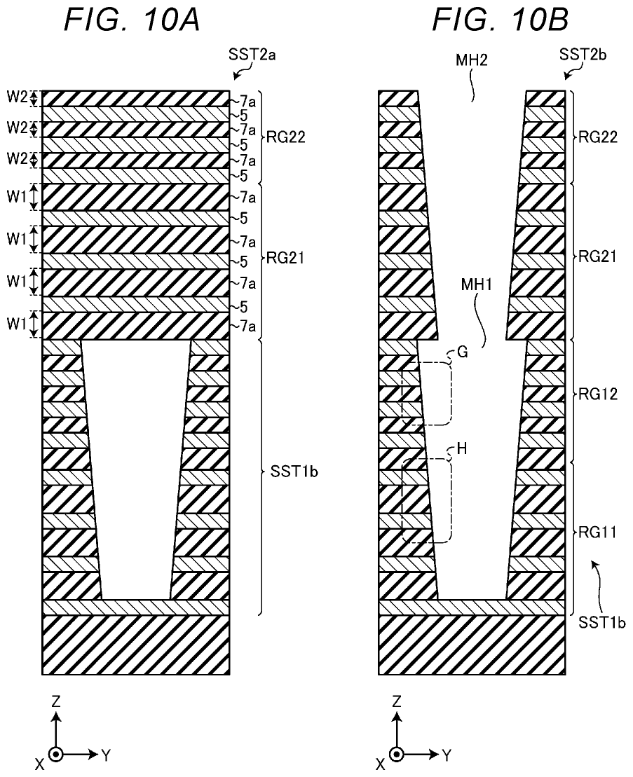

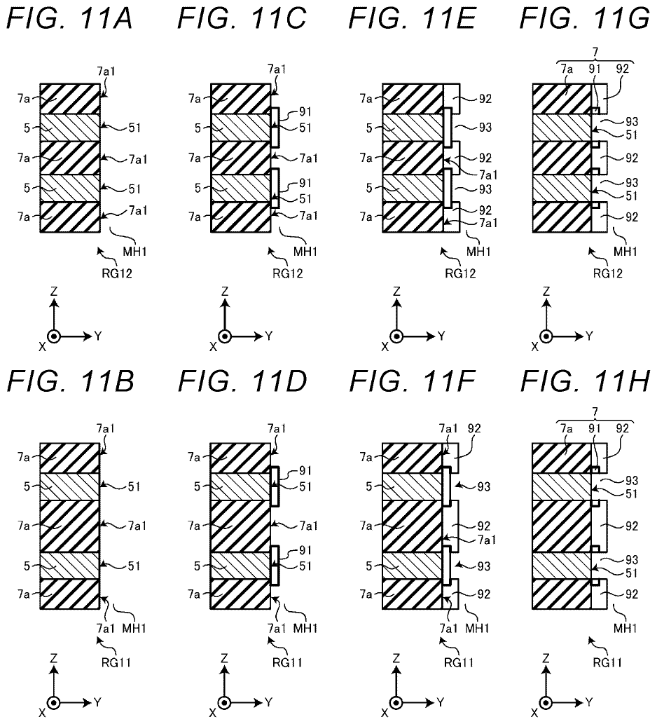

Alternatively, as a second modification example of the embodiment, the semiconductor memory device 1 may be manufactured as shown in FIGS. 9A to 13F. FIGS. 9A and 9B, FIGS. 10A and 10B, FIGS. 11A to 11H, FIGS. 12A to 12H, and FIGS. 13A to 13F are YZ cross-sectional views showing a method of manufacturing the semiconductor memory device 1. FIGS. 11A, 11C, 11E, and 11G, FIGS. 12A, 12C, 12E, and 12G, and FIGS. 13A, 13C, and 13E are enlarged YZ cross-sectional views of a G portion in FIG. 10B. FIGS. 11B, 11D, 11F, and 11H, FIGS. 12B, 12D, 12F, and 12H, and FIGS. 13B, 13D, and 13F are enlarged YZ cross-sectional views of an H portion in FIG. 10B.

In a process shown in FIG. 9A, a transistor is formed on the substrate SUB, a contact plug, a wiring film, a via plug, and the like are formed on the substrate SUB, and an interlayer insulating film is formed around them. Thereby, a peripheral circuit 100 is formed. Thereafter, the interlayer insulating film 81 is deposited on the +Z side of the substrate SUB. The interlayer insulating film 81 may be formed of a material containing an insulating material (for example, a semiconductor oxide such as a silicon oxide) as a main component (see FIG. 1). An insulating layer 7a and a sacrifice layer 5 are alternately deposited a plurality of times on the +Z side of the interlayer insulating film 81 to form a stacked body SST1a. The insulating layer 7a may be formed of a material containing an oxide (for example, a silicon oxide) as a main component. The sacrifice layer 5 may be formed of a material containing a nitride (for example, a silicon nitride) as a main component.

At this time, the insulating layer 7a is deposited to have a film thickness W1 at the Z position corresponding to a region RG11, and the insulating layer 7a is deposited to have a film thickness W2 (<W1) at the Z position corresponding to a region RG12. The sacrifice layer 5 may be deposited to have a substantially constant film thickness.

In a process shown in FIG. 9B, a resist pattern RG1 with an opening for the formation position of a memory hole MH1 is formed on the stacked body SST1a. Anisotropic dry etching is performed using the resist pattern RG1 as a mask to form the memory hole MH1 that reaches the sacrifice layer 5 closest to the −Z side. The memory hole MH1 may be formed such that an average plane width of the region RG11 is smaller than an average plane width of the region RG12.

In a process shown in FIG. 10A, the insulating layer 7a and the sacrifice layer 5 are alternately deposited a plurality of times on the +Z side of a stacked body SST1b to form a stacked body SST2a. The insulating layer 7a may be formed of a material containing an oxide (for example, a silicon oxide) as a main component. The sacrifice layer 5 may be formed of a material containing a nitride (for example, a silicon nitride) as a main component.

At this time, the insulating layer 7a is deposited to have a film thickness W1 at the Z position corresponding to a region RG21, and the insulating layer 7a is deposited to have a film thickness W2 (<W1) at the Z position corresponding to a region RG22. The sacrifice layer 5 may be deposited to have a substantially constant film thickness.

In a process shown in FIG. 10B, a resist pattern RG2 with an opening for the formation position of a memory hole MH2 is formed on the stacked body SST2a. Anisotropic dry etching is performed using the resist pattern RG2 as a mask to form the memory hole MH2 that reaches the memory hole MH1. The memory hole MH2 may be formed such that an average plane width of the region RG21 is smaller than an average plane width of the region RG22.

At this time, the inner surfaces of the memory holes MH1 and MH2 are substantially flat, as shown in FIGS. 11A and 11B. In each of the region RG11 shown in FIG. 11B and the region RG12 shown in FIG. 11A, a surface 7a1 of the insulating layer 7a and a surface 51 of the sacrifice layer 5, which are adjacent to each other in the Z direction, form a continuous and substantially flat surface in a ZY cross-sectional view.

FIGS. 11A and 11B show the memory hole MH1 as an example, but the cross-sectional shape of the memory hole MH2 is substantially the same as the cross-sectional shape of the memory hole MH1. The following description will be mainly focused on the memory hole MH1, but the following description also applies to the memory hole MH2.

In a process shown in FIGS. 11C and 11D, an inhibitor treatment is applied to the inner surface of the memory hole MH1. In the inhibitor treatment, a first treatment gas that is highly reactive with the material of the sacrifice layer 5 and is less reactive with the material of the insulating layer 7a is supplied to the inner surface of the memory hole MH1. Thereby, an insulating film 91 is selectively grown on the surface 51 of the sacrifice layer 5 in each of the region RG11 shown in FIG. 11D and the region RG12 shown in FIG. 11C. The insulating film 91 may be formed of a material containing an insulating material (for example, a silicon oxide) as a main component. At this time, both ends of the insulating film 91 in the Z direction slightly cover the surface 7a1 of the insulating layer 7a.

In a process shown in FIGS. 11E and 11F, a selective growth treatment is applied to the inner surface of the memory hole MH1. In the selective growth treatment, a second treatment gas that is highly reactive with the material of the insulating layer 7a and less reactive with the material of the sacrifice layer 5 is supplied to the inner surface of the memory hole MH1. Thereby, an insulating film 92 is selectively grown on the surface 7a1 of the insulating layer 7a in each of the region RG11 shown in FIG. 11F and the region RG12 shown in FIG. 11E. The insulating film 92 is selectively grown to be thicker than the insulating film 91. The insulating film 92 may be formed of a material containing an insulating material (for example, a silicon oxide) as a main component. At this time, both ends of the insulating film 92 in the Z direction slightly cover the insulating film 91. A step is formed between the end of the insulating film 92 in the Z direction and the surface of the insulating film 91, and thus a concave part 93 is formed on the inner surface of the memory hole MH1. The concave part 93 is recessed toward the sacrifice layer 5 from the surface of the insulating film 92.

In a process shown in FIGS. 11G and 11H, isotropic dry etching or wet etching is performed using the insulating film 92 as a mask. The isotropic dry etching or wet etching is performed until the surface 51 of the sacrifice layer 5 is exposed. Thereby, the surface 51 of the sacrifice layer 5 is exposed at the bottom of the concave part 93 in each of the region RG11 shown in FIG. 11H and the region RG12 shown in FIG. 11G. At this time, the insulating layer 7a and the insulating films 91 and 92 remaining after etching can be integrated as the insulating layer 7.

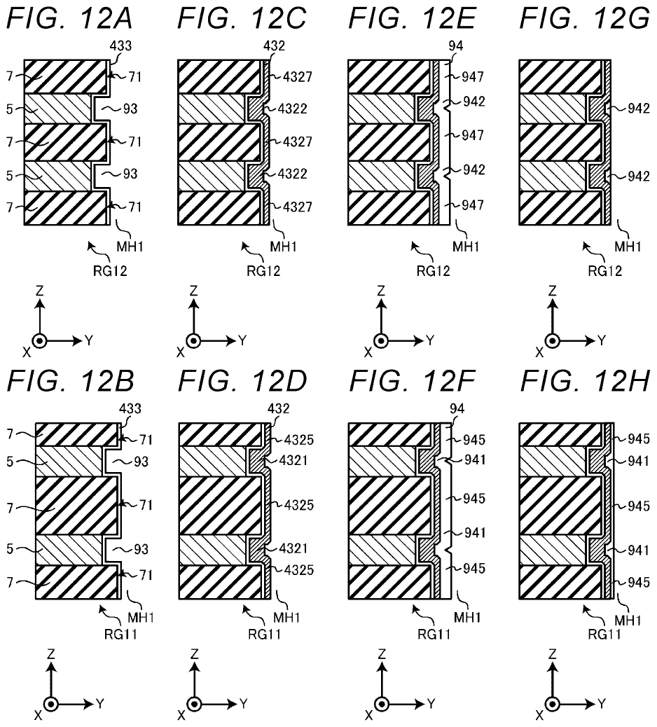

In a process shown in FIGS. 12A and 12B, a block insulating film 433 is deposited on the inner surface and bottom surface of the memory hole MH1. The block insulating film 433 may be formed of a material containing an oxide (for example, a silicon oxide) as a main component. At this time, the block insulating film 433 covers the side surface and bottom surface of the concave part 93 and also covers a surface 71 of the insulating layer 7.

In a process shown in FIGS. 12C and 12D, the charge storage film 432 is deposited on the inner surface and bottom surface of the memory hole MH1. The charge storage film 432 may be formed of a material containing a nitride (for example, a silicon nitride) as a main component. At this time, the charge storage film 432 covers the side surface and bottom surface of the concave part 93 and also covers the surface 71 of the insulating layer 7 via the block insulating film 433.

Thereby, in the region RG11 shown in FIG. 12D, the convex part 4321 and the connection part 4325 of the charge storage film 432 are formed. The convex part 4321 is formed to protrude toward the sacrifice layer 5 from the connection part 4325. On the surface of the convex part 4321 on the memory hole MH1 side, a concave surface is formed at the central part in the Z direction. The connection part 4325 is formed to extend substantially flat in the Z direction.

Similarly, in the region RG12 shown in FIG. 12C, the convex part 4322 and a connection part 4327 of the charge storage film 432 are formed. The convex part 4322 is formed to protrude toward the sacrifice layer 5 from the connection part 4325. On the surface of the convex part 4322 on the memory hole MH1 side, a concave surface is formed at the central part in the Z direction. The connection part 4327 is formed to extend substantially flat in the Z direction.

In a process shown in FIGS. 12E and 12F, a sacrificial film 94 is deposited on the inner surface and bottom surface of the memory hole MH1. The sacrificial film 94 may be formed of any material that has etching resistance against an etchant for the charge storage film 432. The sacrificial film 94 may be formed of amorphous silicon. At this time, the sacrificial film 94 covers the charge storage film 432 from the inside in the XY direction.

Thereby, a convex part 941 and a connection part 945 of the sacrificial film 94 are formed in the region RG11 shown in FIG. 12F. The convex part 941 is formed to protrude toward the sacrifice layer 5 from the connection part 945. On the surface of the convex part 941 on the memory hole MH1 side, a concave surface is formed at the central part in the Z direction. The connection part 945 is formed to extend substantially flat in the Z direction.

Similarly, in the region RG12 shown in FIG. 12E, a convex part 942 and a connection part 947 of the sacrificial film 94 are formed. The convex part 942 is formed to protrude toward the sacrifice layer 5 from the connection part 945. A concave surface is formed at the central part in the Z direction on the surface of the convex part 942 on the memory hole MH1 side. The connection part 947 is formed to extend substantially flat in the Z direction.

In a process shown in FIGS. 12G and 12H, a slimming treatment is performed on the sacrificial film 94. In the slimming treatment, the sacrificial film 94 is selectively thinned by isotropic dry etching or wet etching. At this time, the isotropic dry etching or wet etching is performed under etching conditions such that a connection part 427 is appropriately removed in the region RG12 shown in FIG. 12G and the convex part 942 is selectively left on the concave surface of the convex part 4322.

Here, an average plane width of the memory hole MH1 in the region RG11 is smaller than an average plane width of the memory hole MH1 in the region RG12. Accordingly, an etching rate of the sacrificial film 94 in the region RG11 can be lower than an etching rate of the sacrificial film 94 in the region RG12.

Thereby, in the region RG11 shown in FIG. 12H, in addition to the convex part 941 of the sacrificial film 94, the connection part 945 remains without being completely removed.

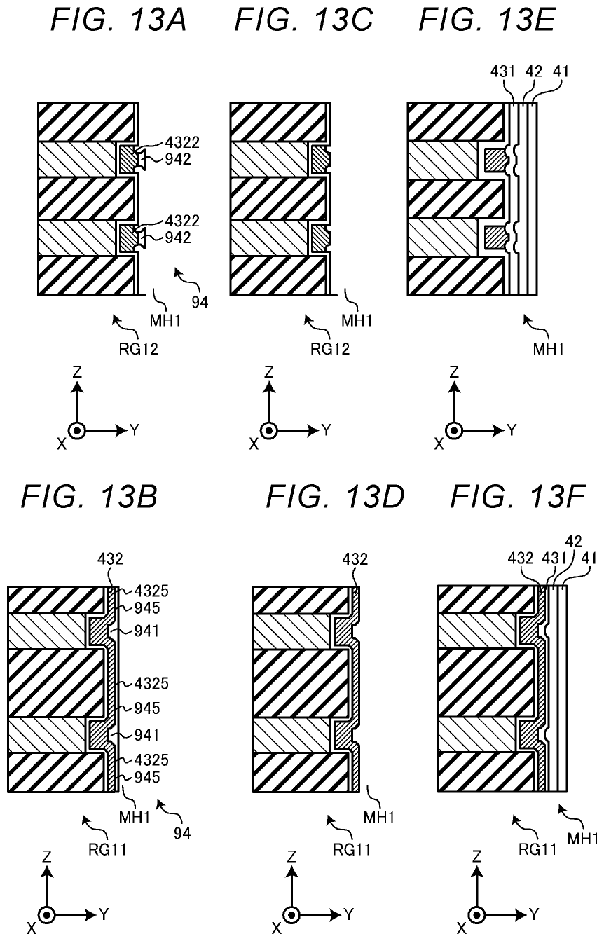

For this reason, in a process shown in FIGS. 13A and 13B, wet etching is performed using an etchant for the charge storage film 432 and using the sacrificial film 94 as a mask. However, in the region RG11 shown in FIG. 13B, the connection part 4325 of the charge storage film 432 is covered with the connection part 945 of the sacrificial film 94 and is difficult to remove.

Meanwhile, in the region RG12 shown in FIG. 13A, the convex part 942 of the sacrificial film 94 selectively covers the convex part 4322 of the charge storage film 432, and thus a connection part 4237 of the charge storage film 432 can be etched and removed. Thereby, the convex part 4322 of the charge storage film 432 can be made into an isolated pattern in the Z direction in the region RG12. At this time, concave surfaces are formed at both ends in the Z direction on the surface of the convex part 4322 on the memory hole MH1 side.

In a process shown in FIGS. 13C and 13D, wet etching is performed using an etchant for the sacrificial film 94. Thereby, the sacrificial film 94 is removed in each of the region RG11 shown in FIG. 13D and the region RG12 shown in FIG. 13C.

In a process shown in FIGS. 13E and 13F, a tunnel insulating film 431 is deposited on the side surface and bottom surface of the memory hole MH1. The block insulating film 433, the charge storage film 432, and the tunnel insulating film 431 at the bottom surface of the memory hole MH1 are selectively removed by anisotropic dry etching. Thereafter, the semiconductor film 42 and the core insulating film 41 are deposited in order on the side surface and bottom surface of the memory hole MH1. Thereby, a columnar body 4 (see FIG. 4) can be formed.

Thereafter, the sacrificial film 5 is removed, and gaps are formed between the plurality of insulating layers 7. A conductive material is filled into the gaps to form the conductive layer 6. Thereby, stacked bodies SST1 and SST2 are formed.

In this manner, the semiconductor memory device 1 can be manufactured by the manufacturing process shown in FIGS. 9A to 13F.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body including a first region and a second region located above the first region in a stacking direction, the stacked body including a plurality of first conductive layers stacked with a first insulating layer in the first region, and a plurality of second conductive layers stacked with a second insulating layer in the second region;
a semiconductor film extending in the stacking direction and penetrating the first region and the second region; and
a charge storage film including a plurality of first convex parts and a plurality of second convex parts, wherein
the plurality of first convex parts are disposed between the plurality of first conductive layers and the semiconductor film in the first region and are continuous with each other in the stacking direction,
each of the plurality of first convex parts protrudes toward the first conductive layer at a position corresponding to the first conductive layer,
the plurality of second convex parts are disposed between the plurality of second conductive layers and the semiconductor film in the second region and are separated from each other in the stacking direction,
each of the plurality of second convex parts protrudes toward the second conductive layer at a position corresponding to the second conductive layer, and
a film thickness of the first insulating layer is larger than a film thickness of the second insulating layer.

2. The semiconductor memory device according to claim 1, wherein
the semiconductor film and the charge storage film are disposed in a memory hole extending in the stacking direction in the stacked body, and
an average plane width of the memory hole in the first region is smaller than an average plane width of the memory hole in the second region.

3. The semiconductor memory device according to claim 1, wherein the charge storage film further includes first connection parts each extending in the stacking direction in the first region and connecting the plurality of first convex parts.

4. The semiconductor memory device according to claim 1, wherein
each of the plurality of first convex parts has a first surface on a side of the semiconductor film including a concave surface at a central part in the stacking direction, and
each of the plurality of second convex parts has a second surface on the side of the semiconductor film including concave surfaces at both ends of the second surface in the stacking direction.

5. The semiconductor memory device according to claim 1, wherein
the stacked body includes a third region between the first region and the second region in the stacking direction, and a plurality of third conductive layers are stacked in the third region with a third insulating layer,
the charge storage film further includes a plurality of third convex parts disposed between the plurality of third conductive layers and the semiconductor film in the third region, separated from each other in the stacking direction, and each protruding toward the plurality of third conductive layers at a position corresponding to the third conductive layer, and
a film thickness of the third insulating layer is smaller than the film thickness of the first insulating layer and larger than the film thickness of the second insulating layer.

6. The semiconductor memory device according to claim 5, wherein
the charge storage film further includes
a first connection part extending in the stacking direction in the first region to connect the plurality of first convex parts, and
a second connection part extending in the stacking direction in the third region to connect the plurality of third convex parts, and
a film thickness of the second connection part is smaller than a film thickness of the first connection part.

7. The semiconductor memory device according to claim 1, wherein in the stacked body, the film thickness of the second insulating layer increases in a stepwise manner as a film thickness of the charge storage film increases from an upper side to a lower side in the second region.

8. The semiconductor memory device according to claim 1, further comprising:
a first oxide film provided between the semiconductor film and the charge storage film; and
a second oxide film provided between the charge storage film and the plurality of first conductive layers and the plurality of second conductive layers,
wherein the charge storage film includes a nitride.

9. The semiconductor memory device according to claim 8, wherein the first oxide film is a tunnel insulating film and the second oxide film is a block insulating film.

10. The semiconductor memory device according to claim 1. further comprising:
a core insulating film provided inside the semiconductor film.

11. A method of manufacturing a semiconductor memory device, comprising:
forming a stacked body by alternately stacking a first sacrificial layer and a first insulating layer having a first film thickness a plurality of times, and alternately stacking a second sacrificial layer and a second insulating layer having a second film thickness a plurality of times, the stacked body having a first region in which a plurality of first sacrificial layers are stacked with the first insulating layer, and a second region which is located above the first region in a stacking direction and in which a plurality of second sacrificial layers are stacked with the second insulating layer;
forming a memory hole extending in the first region and the second region in the stacking direction, the memory hole including a first concave part having an inner circumferential surface recessed toward the first sacrificial layer at a position corresponding to the first sacrificial layer and a second concave part having an inner circumferential surface recessed toward the second sacrificial layer at a position corresponding to the second sacrificial layer;
depositing a charge storage film and a sacrificial film in the memory hole;
etching the sacrificial film to selectively leave the sacrificial film in the first concave part and the second concave part to form a sacrificial pattern;
etching the charge storage film using the sacrificial pattern to selectively leave the charge storage film in the first concave part and the second concave part;
removing the sacrificial pattern;
depositing a semiconductor film in the memory hole;
removing the first sacrificial layers and the second sacrificial layers; and
forming a plurality of conductive layers at locations where the first sacrificial layers and the second sacrificial layers are removed,
wherein a film thickness of the first insulating layer is larger than a film thickness of the second insulating layer.

12. The method according to claim 11,
wherein the sacrificial pattern includes:
a plurality of first portions provided in a plurality of first concave parts in the first region, wherein each of the plurality of first portions is continuous in the stacking direction; and
a plurality of second portions provided in a plurality of second concave parts in the second region, wherein each of the plurality of second portions is separated in the stacking direction.

13. The method according to claim 11,
wherein the charge storage film comprises a nitride material, and the sacrificial film comprises amorphous silicon.

14. The method according to claim 11,
wherein the first concave part and the second concave part are formed by selective growth of insulating films on an inner surface of the memory hole.

15. The method according to claim 11,
wherein the sacrificial pattern is formed by selectively thinning the sacrificial film using isotropic dry etching or wet etching.

16. The method according to claim 11,
wherein the charge storage film is etched using the sacrificial pattern as a mask to form convex parts that protrude toward the conductive layers.

17. The method according to claim 11,
wherein the semiconductor film is deposited after removing the sacrificial pattern and comprises a cylindrical structure surrounding a core insulating film.

18. The method according to claim 11,
wherein the memory hole is formed such that an average plane width of the memory hole in the first region is smaller than in the second region.

19. The method according to claim 11, wherein
the first sacrificial layers and the second sacrificial layers include a nitride, and
the first insulating layer and the second insulating layer include a oxide.

20. The method according to claim 11, further comprising:
forming a block insulating film before depositing the charge storage film in the memory hole; and
forming a tunnel insulating film before depositing the semiconductor film in the memory hole.
